(19) United States
(12) Patent Application Publication
(10) Pub. No.: US 2023/0331543 A1
(43) Pub. Date: Oct. 19, 2023

(54) MEMS DEVICE AND ELECTRO-ACOUSTIC TRANSDUCER

(71) Applicant: AAC Acoustic Technologies (Shenzhen) Co., Ltd., Shenzhen (CN)

(72) Inventors: Yannick Pierre Kervran, HK (FR); Euan James Boyd, EB (GB); Colin Robert Jenkins, EB (GB); Colin Wei Hong Chung, EB (GB); Scott Lyall Cargill, EB (GB)

(21) Appl. No.: 17/723,458

(22) Filed: Apr. 18, 2022

(51) Int. Cl. B81B 3/00

(52) U.S. Cl. CPC B81B 3/0072; B81B 3/007; B81B 2203/0127; B81B 2201/0257

(57) ABSTRACT

Provided is a MEMS device and an electro-acoustic transducer. The MEMS device includes: a substrate having a cavity passing through the substrate; a diaphragm connected to the substrate and covers the cavity. The diaphragm includes oppositely arranged first and second membranes. The first membrane is on one side of the second membrane facing away from the cavity and includes a first protrusion extending away from the second membrane, the first protrusion has a first groove opening towards the second membrane. The second membrane includes a second protrusion extending away from the first membrane and opposite to the first protrusion, the second protrusion has a second groove opening towards the first membrane. By providing first and second protrusions on first and second diaphragms to form a corrugated diaphragm, the internal stress and stiffness of the diaphragm decreases, which effectively increases the mechanical sensitivity of the MEMS device.

### TECHNICAL FIELD

The present disclosure relates to the technical field of micro-electro-mechanical system, and in particular to a MEMS device and an electro-acoustic transducer.

### BACKGROUND

In a conventional micro-electro-mechanical system (MEMS) having a double membrane structure, it includes an upper membrane, a lower membrane, and several support members for connecting the upper membrane and the lower membrane. The support members allow the upper membrane and the lower membrane to be connected in their closest proximity.

A chamber with a sealed volume isolated from air is formed between the upper membrane, the lower membrane and two adjacent support members. With a proper design and a proper manufacturing technology, the sealed volume of such a chamber can be kept under a decreased atmospheric pressure or in the absence of air (i.e., vacuum).

The purpose of the support member is to keep the membrane flat, or at least limit/control the bending/deformation of the membrane between support members, so as to avoid the upper membrane and the lower membrane from folding over each other (resulting of a significant pressure difference) when the sealed volume of the chamber is at a decreased atmospheric pressure and the outside is at ambient atmospheric pressure.

However, the stiffness of this double membrane structure increases as the pressure difference between the inside and outside increases. The stiffness is defined as the inverse ratio with respect to the mechanical sensitivity, so this situation leads to a poor mechanical sensitivity.

### SUMMARY

In view of the above problems, the present disclosure provides a MEMS device and an electro-acoustic transducer to solve the technical problems in the related art, which can increase the mechanical sensitivity of the MEMS device.

In a first aspect, the present disclosure provides a MEMS device, including: a substrate having a cavity passing through the substrate; and a diaphragm connected to the substrate and covers the cavity. The diaphragm includes a first membrane and a second membrane that are arranged opposite to each other, and the first membrane is arranged on one side of the second membrane facing away from the cavity. The first membrane includes a first protrusion protruding from the first membrane and extending in a direction away from the second membrane, and the first protrusion is provided with a first groove opening towards the second membrane. The second membrane includes a second protrusion protruding from the second membrane and extending in a direction away from the first membrane, the second protrusion is arranged opposite to the first protrusion, and the second protrusion is provided with a second groove opening towards the first membrane.

In the technical solution of the present disclosure, by providing a first protrusion on the first membrane and a second protrusion on the second membrane, the first protrusion and the second protrusion are combined to form a corrugated diaphragm. This can decrease the internal stress of the formed diaphragm. With the increase of the pressure difference between the inside and the outside, the stiffness of the diaphragm is decreased, which effectively increases the mechanical sensitivity of the MEMS device.

As an improvement, a plurality of first protrusion and a plurality of second protrusions are provided and are arranged at intervals along a radial direction of the diaphragm.

As an improvement, the first protrusion and the second protrusion are arranged close to an edge of the diaphragm.

As an improvement, the first protrusion and the second protrusion are arranged close to a center of the diaphragm.

As an improvement, the first protrusion and the second protrusion have the same shape and size.

As an improvement, the first protrusion and the second protrusion have a shape of a rectangle, a trapezoid, or a triangle when perpendicular to a surface of the diaphragm.

As an improvement, a support member is provided between the first membrane and the second membrane. A first end of the support member is connected to the first membrane and located between two adjacent first protrusions, a second end of the support member is connected to the second membrane and is located between two adjacent second protrusions.

As an improvement, the first membrane, the second membrane and two adjacent support members are enclosed to form an accommodating cavity, and the accommodating cavity is provided therein with a counter electrode.

As an improvement, the accommodating cavity is hermetically sealed, and an internal pressure of the accommodating cavity is less than an external atmospheric pressure.

As an improvement, a pressure difference is generated between an internal pressure in the accommodating cavity and an external ambient pressure, and a mechanical sensitivity of a structure formed by the first membrane and the second membrane increases as the pressure difference increases.

As an improvement, the first membrane and the second membrane are both made of a conductive material or include an insulating film having a conductive element.

As an improvement, the counter electrode includes a single conductor, so that a first capacitor is formed between the first membrane and the single conductor, and a second capacitor is formed between the second membrane and the single conductor.

As an improvement, the counter electrode includes a first surface facing the first membrane and a second surface facing the second membrane. Conductive elements are respectively arranged on the first surface and the second surface, such that a first capacitor is formed between the first membrane and the conductive element on the first surface, and a second capacitor is formed between the second membrane and the conductive element on the second surface.

In a second aspect, the present disclosure also provides an electro-acoustic transducer, including the aforementioned MEMS device and a circuit device electrically connected to the MEMS device.

The above description is only an overview of the technical solution of the present disclosure. In order to understand the technical means of the present disclosure more clearly, it can be implemented in accordance with the content of the specification, and in order to make the above and other purposes, features and advantages of the present disclosure more obvious and understandable. The following description shows detailed embodiments of the present disclosure.

### BRIEF DESCRIPTION OF DRAWINGS

Through reading the detailed description of the following preferred embodiments, various other advantages and benefits will become clear to those of ordinary skill in the art. The drawings are only used for the purpose of illustrating the preferred embodiments, and are not considered as limitations to the present disclosure. In all the drawings, the same reference signs are used to denote the same components.

FIG. 1 is a schematic structural diagram of a first diaphragm;

FIG. 2 is a schematic structural diagram of a second diaphragm;

FIG. 3 is a schematic structural diagram of a third diaphragm;

FIG. 4 is a schematic structural diagram of a fourth diaphragm;

FIG. 5 is a top view of the first membrane of the diaphragm;

FIG. 6 is a schematic structural diagram of an electro-acoustic transducer.

In the drawings, the drawings may not be drawn to actual scale.

### REFERENCE SIGNS

10-substrate, 11-cavity;
20-diaphragm, 21-first membrane, 211-first protrusion, 212-first
groove, 22-second membrane, 221-second protrusion, 222-second
groove, 23-accommodation cavity
30-support member;
40-counter electrode, 41-conductive element;
50-spoke;
100-electro-acoustic transducer;
200-MEMS device;
300-circuit device.

### DESCRIPTION OF EMBODIMENTS

Embodiments described below with reference to the drawings are exemplary, and are only used to explain the present disclosure, and cannot be construed as limiting the present disclosure.

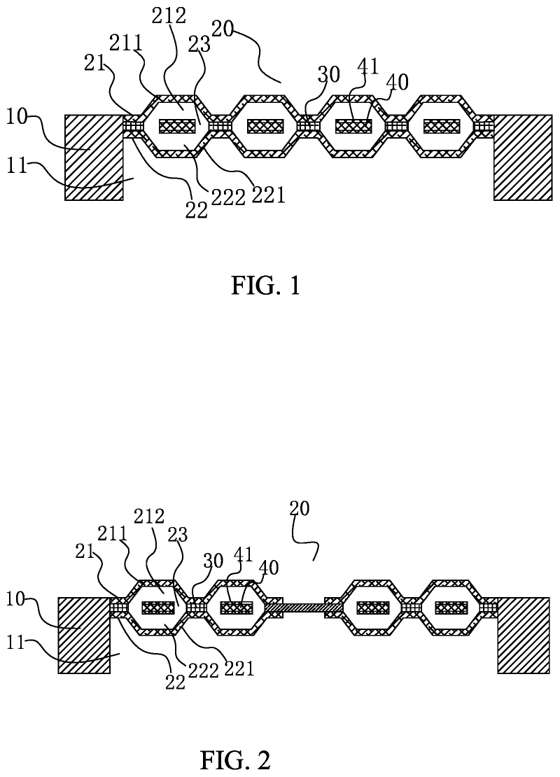

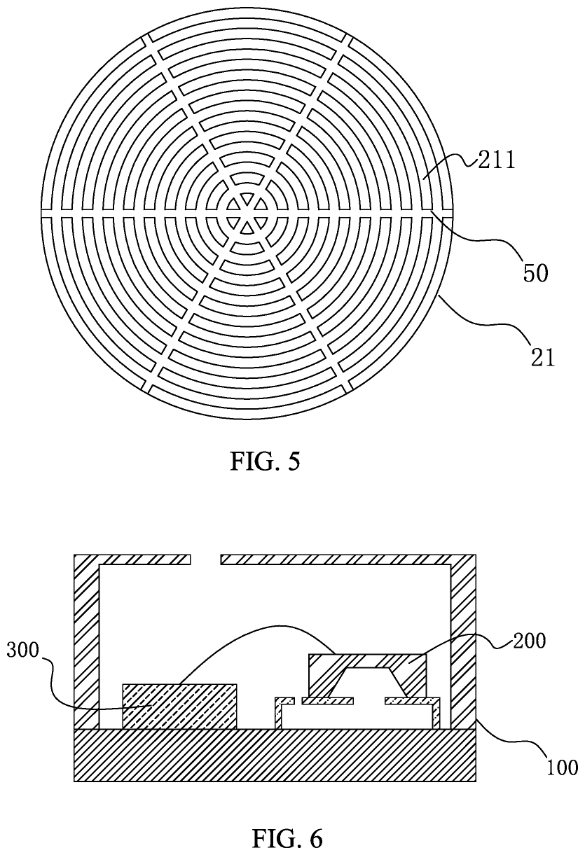

Referring to FIG. 1 to FIG. 5, the present disclosure provides a MEMS device 200, including:

A substrate 10, a cavity 11 passes through the substrate 10. Optionally, the inner contour surface of the cavity 11 has a circular structure.

A diaphragm 20 is connected to the substrate 10 and covers the cavity 11. The diaphragm 20 includes a first membrane 21 and a second membrane 22 disposed opposite to each other. The first membrane 21 is located in the cavity 11 away from the second membrane 22. In this embodiment, the first membrane 21 and the second membrane 22 are both concentrically arranged circular structures. A preset gap is provided between the first membrane 21 and the second membrane 22. The first membrane The first membrane 21 and the second membrane 22 may be made of a conductive material or include an insulating film having a conductive element.

The first membrane 21 includes a first protrusion on 211 protruding from the first membrane 21 protrusion. The first protrusion 211 extends in a direction facing away from the second membrane 22. The part of the first membrane 21 except for the first protrusion 211 is flat. The first protrusion 211 is provided with a first groove 212 opening towards the second membrane 22. The shape of the first groove 212 may adapt to the cross section of the first protrusion 211. An upper surface of the first membrane 21 is facing away from the cavity 11, and the upper surface of the first protrusion 211 is higher than the upper surface of the first membrane 21. It can be understood that a part of the first membrane 21 is bent (including the first protrusions 211) to form a corrugation shape, and the other part is not bent, and has, for example, a flat structure.

The second membrane 22 includes a second protrusion 221 protruding from the second membrane 22. The second protrusion 221 extends in a direction facing away from the first membrane 21. The part of the second membrane 22 except for the second protrusion 221 is flat. The second protrusion 221 and the first protrusion 211 are disposed opposite to each other. The second protrusion 221 is provided with a second groove 222 opening towards the first membrane 21. The shape of the second groove 222 may adapt to the cross section of the second protrusion 221. A lower surface of the second membrane 22 is a surface close to the cavity 11, and the lower surface of the second protrusion 221 is lower than the lower surface of the second membrane 22. It can be understood that a part of the second membrane 22 is bent (including the second protrusions 221) to form a corrugation shape, and the other part is in a not bent and has, for example, a flat structure.

Optionally, the shapes and sizes of the first protrusions 211 and the second protrusions 221 are the same to form a regular corrugation shape, so that the stress distribution on the entire diaphragm 20 is uniform, and at the same time, it is advantageous for the forming process. The shape of the first protrusion 211 and the second protrusion 221 perpendicular to the surface of the diaphragm 20 may be a regular shape such as rectangular, trapezoidal, or triangular, or may be an irregular shape of a rounded rectangle or other polygons. An angle of the inclined surface of the first protrusion 211 and the second protrusion 221 is greater than 0°, and less than or equal to 90°. Those skilled in the art can understand that the shape of the first protrusion 211 and the second protrusion 221 perpendicular to the surface of the diaphragm 20 can be a regular pattern or an irregular pattern, which is not limited herein.

The first protrusion 211 and the second protrusion 221 together form the corrugation of the diaphragm 20, so that the diaphragm 20 can have its tensile stress decreased and can withstand greater sound pressure, due to the fact that the corrugated structure allows a decrease of the tensile stress in the diaphragm. The first protrusion 211 protrudes away from the cavity 11, and the second protrusion 221 protrudes toward the cavity 11, so that the formed diaphragm 20 has a smaller internal tensile stress. With the increase of the pressure difference between outside and inside, the stiffness of the membrane of the diaphragm 20 is decreased, which effectively increases the mechanical sensitivity of the MEMS device 200.

In some embodiments, a plurality of first protrusions 211 and a plurality of second protrusions 221 are provided and are radially arranged along the diaphragm 20 at intervals, such that the diaphragm 20 is provided with at least two corrugations. The corrugations may be symmetrically distributed with respect to the center of the diaphragm 20. When the diaphragm 20 has a disc-shaped structure, the corrugations may be distributed in a circle around the center of the disc-shaped structure.

When the pressure difference between the internal pressure of the diaphragm 20 and the external ambient pressure exceeds a preset threshold, multiple corrugations can effectively increase the mechanical sensitivity of the diaphragm 20 due to a decrease of the tensile stress of the diaphragm 20 in the horizontal direction (parallel to the surface of the diaphragm 20).

It is appreciated that, the number of the corrugations may have an optimum value so that the diaphragm 20 possesses an optimum mechanical sensitivity. In some embodiments, the number of the corrugations may be 7. Those skilled in the art can clearly understand that, this optimum number is based on specific experimental conditions, changes may be made according to different practical situations, which is not limited herein.

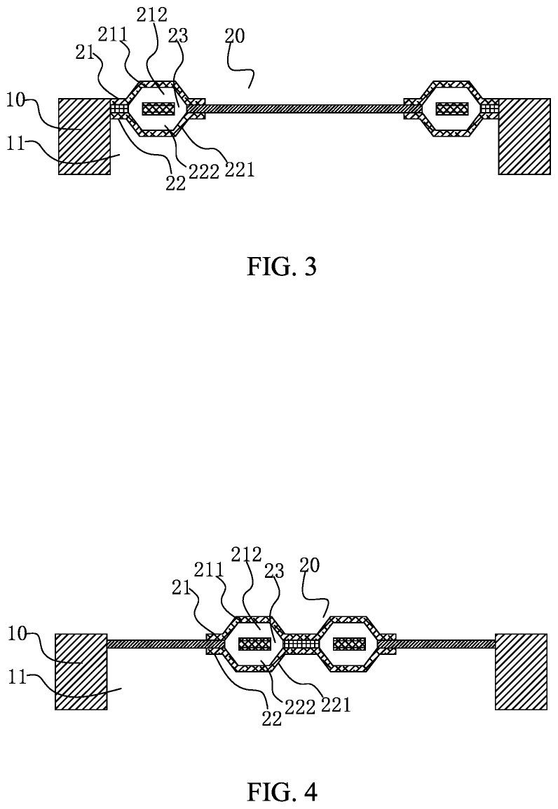

Referring to FIG. 3 and FIG. 4, the first protrusions 211 and second protrusions 221 is provided near an edge of the diaphragm 20. The number of the first protrusions 211 and second protrusions 221 may be one or more, in order to avoid significant deformation of the diaphragm 20.

Referring to FIG. 2, the first protrusion 211 and the second protrusion 221 are arranged close to the center of the diaphragm 20, so that the double membrane structure has the highest compliance with a higher mechanical sensitivity than those diaphragms formed by conventional single-layer deposition material.

Referring to FIG. 1 to FIG. 5, a support member 30 is provided between the first membrane 21 and second membrane 22. The support member 30 extends along a direction perpendicular to the diaphragm 20. The support member 30 has a first end connected to the first membrane 21 and located between two adjacent first protrusions 211. A second end of the support member 30 is connected to the second membrane 22 and is located between two adjacent second protrusions 221. As a result, the first membrane 21 and the second membrane 22 are mechanically coupled to each other. The support member 30 is optionally made of silicon nitride.

The support member 30 may be an integral wall-shaped structure, or may be provided with a space therein. The space may be filled with a filler material, and the filler material may be an oxide, such as silicon oxide. Alternatively, the space may be empty. Slots may be provided in the space to allow air or etching solution from the external environment to enter the space to release the filler material, thereby increasing the compliance of the first membrane 21 and the second membrane 22, and reducing the inter-plate capacitance between the first membrane 21 and the second membrane 22.

The support member 30 may be integrally formed with one of the first membrane 21 and the second membrane 22. Alternatively, after the first membrane 21 and the second membrane 22 are assembled together, a support member 30 is formed therebetween.

The first membrane 21, the second membrane 22 and two adjacent support members 30 are enclosed to form an accommodating cavity 23. The accommodating cavity 23 is hermetically sealed, and in some embodiments, its internal pressure is lower than the external atmosphere. In some embodiments, the internal pressure of the accommodating cavity 23 may be in a range of 0.1 atm to 0.2 atm. In some embodiments, the accommodating cavity 23 is vacuum.

A pressure difference is generated between an internal pressure in the accommodating cavity 23 and an external ambient pressure, and a mechanical sensitivity of the structure formed by the first membrane 21 and the second membrane 22 increases as the pressure difference increases. That is, a stiffness of the structure formed by the first membrane 21 and the second membrane 22 decreases as the pressure difference increases.

Referring to FIG. 2, the accommodating cavity 23 is provided with a counter electrode 40, and the counter electrode 40 is suspended in the accommodating cavity 23 through spokes 50. The counter electrode 40 extends along the diaphragm 20 in the circumferential direction. There is no mechanical coupling between the counter electrode 40 and the support member 30, and a plurality of counter electrodes 40 and a plurality of support members 30 are alternately arranged along the radial direction of the diaphragm 20.

The conductive members 41 are disposed on opposite upper and lower surfaces of the electrode 40. The first membrane 21 is spaced from the conductive element 41 of the counter electrode 40, so that a first capacitor is formed therebetween. The second membrane 22 is spaced from the conductive element 41 of the corresponding counter electrode 40, so that a second capacitor is formed therebetween. In response to the pressure applied to the first membrane 21 and the second membrane 22, the first membrane 21 and the second membrane 22 are movable relative to the corresponding counter electrode 40, thereby changing the distance between the first membrane 21, the second membrane 22 and corresponding counter electrodes 40 of the support member 30. As a result, the capacitance is changed to output electrical signals accordingly.

Alternatively, the counter electrode 40 includes a single conductor, so that the first capacitor is formed between the first membrane 21 and the single conductor, and the second capacitor is formed between the second membrane 22 and the single conductor.

Based on the above embodiments, the present disclosure also provides an electro-acoustic transducer 100, as shown in FIG. 6, including the aforementioned MEMS device 200 and a circuit device 300 (ASIC) electrically connected to the MEMS device 200. The electro-acoustic transducer 100 can be a microphone or a speaker, etc.

The structure, features, and effects of the present disclosure are described in detail above based on the embodiments shown in the drawings. The above are only preferred embodiments of the present disclosure. However, the present disclosure does not limit the scope of implementation as shown in the drawings. Any equivalent changes or modified embodiments made in accordance with the concept of the present disclosure, which still do not exceed the spirit covered by the specification and drawings, should fall within the protection scope of the present disclosure.

What is claimed is:

1. A micro-electro-mechanical system (MEMS) device, comprising:
a substrate having a cavity passing through the substrate; and
a diaphragm connected to the substrate and covers the cavity, wherein the diaphragm comprises a first membrane and a second membrane that are arranged opposite to each other, and the first membrane is arranged on one side of the second membrane facing away from the cavity,
wherein the first membrane comprises a first protrusion protruding from the first membrane and extending in a direction away from the second membrane, and the first protrusion is provided with a first groove opening towards the second membrane, and
the second membrane comprises a second protrusion protruding from the second membrane and extending in a direction away from the first membrane, the second protrusion is arranged opposite to the first protrusion, and the second protrusion is provided with a second groove opening towards the first membrane.

2. The MEMS device as described in claim 1, wherein a plurality of first protrusion and a plurality of second protrusions are provided and are arranged at intervals along a radial direction of the diaphragm.

3. The MEMS device as described in claim 1, wherein the first protrusion and the second protrusion are arranged close to an edge of the diaphragm.

4. The MEMS device as described in claim 1, wherein the first protrusion and the second protrusion are arranged close to a center of the diaphragm.

5. The MEMS device as described in claim 1, wherein the first protrusion and the second protrusion have the same shape and size.

6. The MEMS device as described in claim 1, wherein the first protrusion and the second protrusion have a regular shape of a rectangle, a trapezoid, or a triangle or an irregular shape of a rounded rectangle or a polygon, when perpendicular to a surface of the diaphragm.

7. The MEMS device as described in claim 1, wherein a support member is provided between the first membrane and the second membrane, a first end of the support member is connected to the first membrane and located between two adjacent first protrusions, a second end of the support member is connected to the second membrane and is located between two adjacent second protrusions.

8. The MEMS device as described in claim 7, wherein the first membrane, the second membrane and two adjacent support members are enclosed to form an accommodating cavity, and the accommodating cavity is provided therein with a counter electrode.

9. The MEMS device as described in claim 8, wherein the accommodating cavity is hermetically sealed, and an internal pressure of the accommodating cavity is less than an external atmospheric pressure.

10. The MEMS device as described in claim 8, wherein a pressure difference is generated between an internal pressure in the accommodating cavity and an external ambient pressure, and a mechanical sensitivity of a structure formed by the first membrane and the second membrane increases as the pressure difference increases.

11. The MEMS device as described in claim 8, wherein the first membrane and the second membrane are both made of a conductive material or comprise an insulating film having a conductive element.

12. The MEMS device as described in claim 8, wherein the counter electrode comprises a single conductor, so that a first capacitor is formed between the first membrane and the single conductor, and a second capacitor is formed between the second membrane and the single conductor.

13. The MEMS device as described in claim 8, wherein the counter electrode comprises a first surface facing the first membrane and a second surface facing the second membrane, and conductive elements are respectively arranged on the first surface and the second surface, such that a first capacitor is formed between the first membrane and the conductive element on the first surface, and a second capacitor is formed between the second membrane and the conductive element on the second surface.

14. An electro-acoustic transducer, comprising an MEMS device and a circuit device electrically connected to the MEMS device, wherein the MEMS device comprises:
a substrate having a cavity passing through the substrate;
a diaphragm connected to the substrate and covers the cavity, wherein the diaphragm comprises a first membrane and a second membrane that are arranged opposite to each other, and the first membrane is arranged on one side of the second membrane facing away from the cavity,
wherein the first membrane comprises a first protrusion protruding from the first membrane and extending in a direction away from the second membrane, and the first protrusion is provided with a first groove opening towards the second membrane, and
the second membrane comprises a second protrusion protruding from the second membrane and extending in a direction away from the first membrane, the second protrusion is arranged opposite to the first protrusion, and the second protrusion is provided with a second groove opening towards the first membrane.
